(19) United States
(12) Patent Application Publication
(10) Pub. No.: US 2012/0054564 A1
(43) Pub. Date: Mar. 1, 2012

(54) Method and apparatus to test memory using a regeneration mechanism

(76) Inventors: Abhishek Kumar Tiwary, Varanasi (IN); Anubhav Singh, Noida (IN); Anuj Verma, New Delhi (IN); Arnab Bhattacharya, Sonarpur (IN)

(21) Appl. No.: 12/807,134

(22) Filed: Aug. 27, 2010

(51) Int. Cl. G11C 29/04; G06F 11/22

(52) U.S. Cl. 714/718; 714/E11.145

(57) ABSTRACT

A method and a system for testing memory blocks using a built-in-self-test (BIST) block using a regeneration mechanism. The method includes generation of a test pattern by executing a pre-defined algorithm to test a memory address of a memory block. The test pattern is stored at the memory address, and then the stored data is read from the memory address. The read data is send to a comparator for comparison with a background data. The background data corresponds to the test pattern and is regenerated by a regeneration block corresponding to clock cycles taken for storing the test pattern in the memory address. The stored data is read from the memory address. The comparator generates a validity signal based on the comparison of the background data with the read data.

### FIELD OF THE INVENTION

The present invention generally relates to the field of semiconductor memories. More particularly, the invention relates to a method and a system for testing the semiconductor memories using a built-in-self-test (BIST) block.

### BACKGROUND OF THE INVENTION

In today's world, most of Integrated Circuits (ICs) are complete systems having hundreds of different circuits. The circuits include, but are not limited to, processors, amplifiers, multiplexers, encoders, filters, and memories. All these circuits are required to be optimized and to be operated at high speed. Individual testing of the circuits is required to ensure the desired performance of these circuits. Testing of different circuits is done at various stages during IC manufacturing. For some circuits like memories, a test circuit is introduced within the ICs. The test circuit performs an exhaustive test at maximum possible speed for a circuit. The maximum possible speed for a system is equivalent to memory clock speed. Built-in-self-test (BIST) block is an example of a test circuit used for testing the memory blocks available in an IC.

FIG. 1 shows a typical block diagram of a BIST inserted memory embedded in a system-on-chip (SoC). In FIG. 1, a BIST block 102 has a BIST circuit 104 with combinational delay 106 offered by the BIST circuit 104. The BIST block 102 is directly connected to a memory block 108. Testing of the memory block 108 is performed at lower speed by the BIST block 102 due to the combinational delay 106. An AT-Speed testing of the memory block 108 is desirable to test the memory block 108 at maximum possible speed for a system. So, it is desirable to improve the architecture of the BIST block 102 for AT-Speed testing.

FIG. 2 shows an improved BIST inserted in a memory, which in turn is embedded in a SOC. An improved BIST block 202 has a BIST circuit 204 along with a pipeline register 206. As compared to the previous approach, combinational delay offered by the BIST circuit 204 is broken into smaller chunks, combinational delay 208 and combinational delay 210. The BIST block 202 is connected with a memory block 212. The combinational delay is reduced due to the pipeline register 206, and the operational speed of the BIST block 202 is significantly increased. Due to two combinational delays offered by the BIST block 202, AT-Speed testing of the memory blocks becomes possible.

Further, the pipeline register 206 enables concurrent execution of operations, which reduces the memory clock cycles. Due to the parallel execution of operations, the memory remains idle for less time. This leads to the testing of memories with maximum fault coverage, which is defined as Max Speed™ testing. In Max Speed testing the memory generally does not shift into idle state during memory operations like read or write operations. For example, Max Speed testing can be applied for a read operation that has a sequence of three operations: first, generation of input signals during which memory is idle; second, operation performed by the memory; and third, a comparison operation during which the memory is again idle. By using pipeline registers, the second and third operations can be executed in conjunction with the first operation. So, effectively the memory will remain idle for less time and more exhaustive testing can be performed. However, by connecting the pipeline register 206, the area requirement of the circuit increases significantly.

FIG. 3 illustrates an exemplary functional block diagram of a BIST block 302. The BIST block 302 has a state machine 304, which defines various states for operation and provides the current state of operation to BIST input signal generator 306. The BIST block 302 further includes two pipeline registers 308 and 310 that can be used for AT-Speed testing. For a particular state in the state machine 304, an operation-set is defined as compound-operations performed by the BIST block 302. A compound-operation is a sequence of atomic-operations performed on a single address. Atomic operation is a basic operation performed on the memory, for example, read, and write. Each operation consumes a few clock cycles in execution and is expressed in terms of memory clock cycles. On the basis of current state of operation, the BIST input signal generator 306 generates a test pattern for the memory address. The test pattern for the memory address is stored in the pipeline register 308, which is placed between a memory 312 and the BIST input signal generator 306. A multiplexer 314 connected between the pipeline register 308 and the memory 312 is used to select whether the memory 312 will store an external data 320 for normal operation or store the test pattern available in pipeline register 308 for testing. In the next clock cycle, the test pattern is passed to the memory 312 to write at the memory address. After writing the test pattern, it is read from the memory address in subsequent clock cycles and is stored in the pipeline register 310. In the subsequent clock cycle, the data stored in the pipeline register 310 is sent to a comparator 316. Further, pipeline register 326 receives a background data corresponding to the test pattern generated by the signal generator 306 a few cycles back. The comparator 316 compares the background data with the data received from the pipeline register 310 and sends a pass/fail signal 322 to a diagnostic block 318. The diagnostic block 318 generates diagnosis data 324 in case of test failure. The waveforms for BIST signals and memory signals are shown in FIG. 4. During AT-Speed testing, the BIST block 302 should run at memory clock speed in order to reduce testing time and to enhance the fault detection capability. By introducing the pipeline registers 308 and 310 in the BIST block 302, the operational speed of the BIST block 302 increased threefold. However, the area requirement of the IC also increases.

FIG. 4 shows waveform diagrams for AT-Speed testing. At a particular time instance 402, the BIST input signal generator 306 generates control signal 404 for address 04. At the same time instance 402, the pipeline register 308 holds the signal values generated by input signal generator at a previous clock cycle i.e., prior to time instance 402. At the same time instance 402, the comparator 316 receives memory output signal 406 delayed by two memory clock cycles. At the next clock cycle (after time instance 402) the comparison for address data 03 takes place. Therefore it is required to delay the background data by two clock cycles.

FIG. 5 shows waveforms for Max Speed testing of the memory 312 discussed in FIG. 3. The objective of the Max-Speed testing is to run the memory 312 in an active environment. During Max-Speed testing, the memory 312 can change address and read out different data from different addresses at every memory clock cycle. Hence, every operation effectively takes a unit clock cycle, which enables timing and stress testing. With Max-Speed testing, the operations performed by the AT-Speed testing can be performed in fewer clock cycles. Various operations can be performed in parallel, for example, input signal generation at the BIST input signal generator 306 for address 04, memory operation for address 03 and comparison operations by the comparator 316 for address 02 occurs in parallel. The parallel execution of the events leads to the Max-Speed testing of the memory 312.

For AT-Speed testing of the memory 312 as shown in FIG. 3, a delay of two clock cycles is required to store the background data as shown in FIG. 4. To overcome this limitation, additional pipeline register 326 is used to store the background data corresponding to a previous test pattern. The additional pipeline register 326 is placed between the comparator 316 and the BIST input signal generator 306 as shown in FIG. 3. But adding pipeline registers increases the area required by the BIST block 302 to be fabricated. For a memory configuration 100K×64 with two pipeline registers at the input and output of memory, the area required on a 130 nm technology for a fast process is 11438 units. By connecting the additional pipeline registers before the comparator the area requirement increased by 152%.

In case the pipeline registers are not used, any memory address will be tested only after the comparison of read data with background data for a previous address. In this approach a large number of clock cycles will be required for testing each memory address and memory has to remain idle for a longer period of time. Therefore, a need exist for an efficient method and a system for testing a memory using both AT-Speed and Max-Speed testing. Further, the area requirement of the BIST block should be minimized.

### SUMMARY OF THE INVENTION

The present invention discloses a method for testing memory blocks using a built-in-self-test (BIST) block using a regeneration mechanism. In this method, a test pattern is generated by executing a pre-defined algorithm to test a memory address of a memory block. The test pattern is stored at the memory address and then the data is read from the memory address. The read data is send to a comparator for comparison with a background data. The background data corresponds to the test pattern. Further, the background data is regenerated by a regeneration block taking into account the clock cycles taken for storing the test pattern in the memory address and the clock cycles taken for reading the stored data from the memory address. The comparator generates a pass or a fail signal based on the comparison of the background data regenerated corresponding to the test pattern with the read data.

The present invention discloses a built-in-self-test (BIST) architecture for testing memory blocks using a regeneration block. The BIST architecture comprises a state machine for generating a test pattern using a pre-defined algorithm. Further, the test pattern is stored in a memory address through a set of pipeline registers. Data of the stored test pattern in the memory address is read and sent to a comparator through a set of pipeline registers. Thereafter, the comparator compares the read data with a background data. The background data is generated by a regeneration block, wherein the background data corresponds to clock cycles taken for storing and the clock cycles taken for reading the test pattern in the memory address. The comparator generates a validity signal based on the comparison of the background data with the data read from the memory address.

The method and system for testing memory blocks using a BIST block disclosed in the present invention is suitable for AT-Speed testing and for Max-Speed testing. Further, in an embodiment of the invention, use of the pipeline registers is optional, hence the area required to fabricate the BIST block can be optimized.

### BRIEF DESCRIPTION OF THE FIGURES

The accompanying figures, wherein like reference numerals refer to identical or functionally similar elements throughout the separate views, and which, together with the detailed description below, are incorporated in and form part of the specification, serve to further illustrate various embodiments and explain various principles and advantages, all in accordance with the present invention.

The embodiments of the invention will hereinafter be described in conjunction with the appended drawings, provided to illustrate and not to limit the invention, wherein like designations denote like elements, and in which:

FIG. 1 illustrates a block diagram of a BIST inserted memory;

FIG. 2 illustrates a BIST inserted memory with a pipeline register;

FIG. 3 illustrates a functional block diagram of BIST connected with memory;

FIG. 4 illustrates a waveform diagram for AT-Speed testing of memory;

FIG. 5 illustrates a waveform diagram for Max-Speed testing of memory;

FIG. 6 illustrates a functional block diagram of BIST with regeneration block, in accordance with an embodiment of the present invention;

FIG. 7 is a flow diagram illustrating a method of testing a memory address, in accordance with an embodiment of the present invention;

FIG. 8a illustrates waveforms for basic MARCHC operation;

FIG. 8b illustrates waveforms for basic MARCHC operation at a last memory address;

FIG. 9a illustrates waveforms for a checkerboard algorithm at a first memory address;

FIG. 9b illustrates waveforms for a unique address algorithm at a first memory address;

FIG. 9c illustrates waveforms for a checkerboard algorithm at a last memory address; and

FIG. 9d illustrates waveforms for a unique address algorithm at a last memory address.

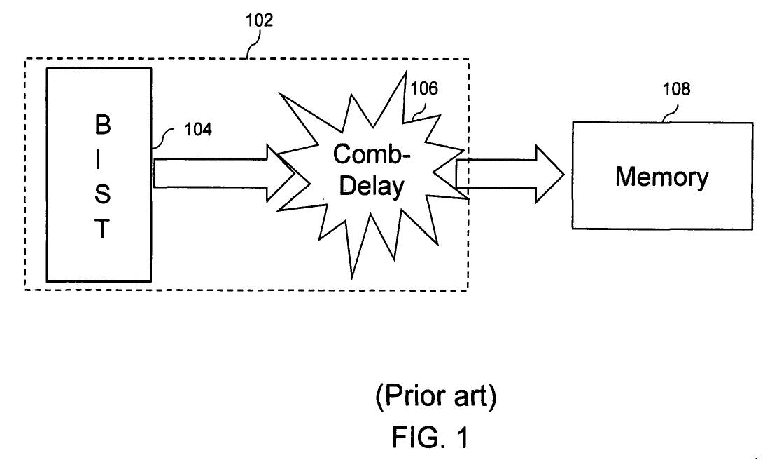

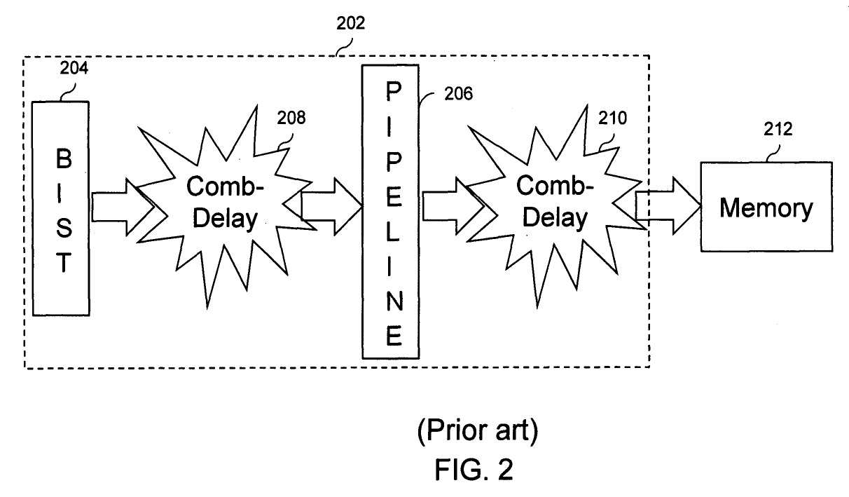

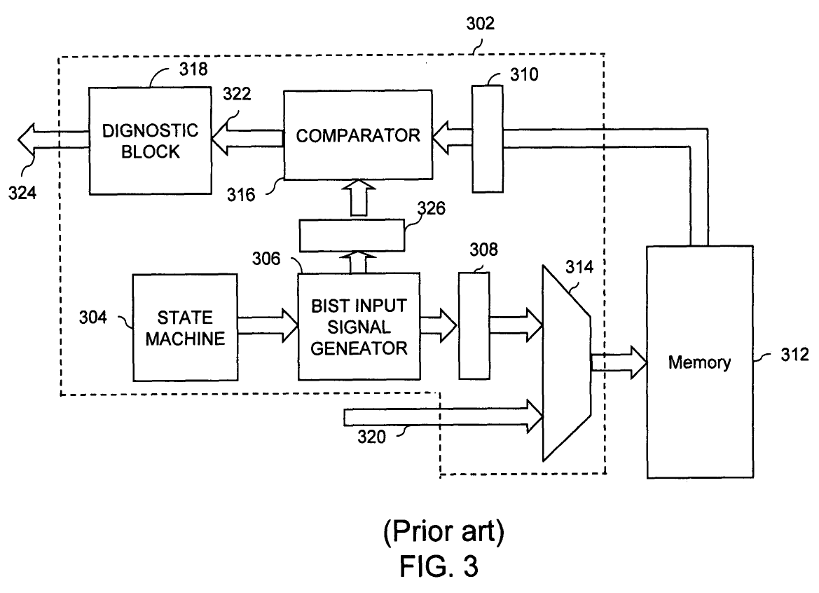

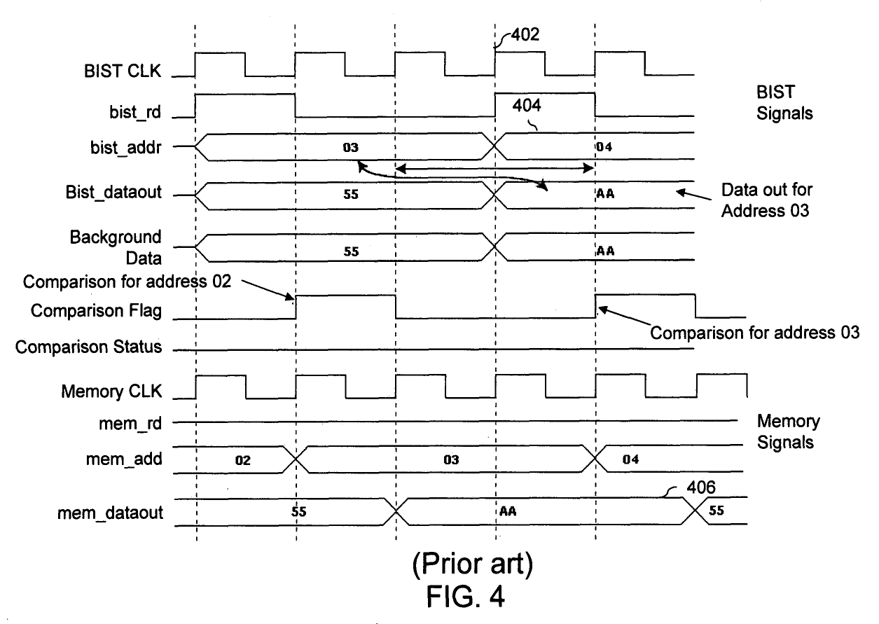

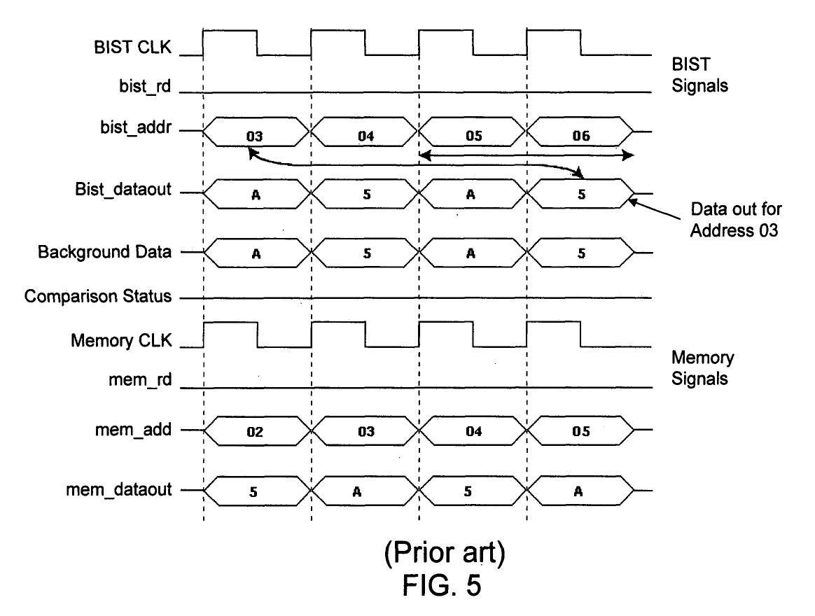

### DETAILED DESCRIPTION OF THE INVENTION

Before describing in detail the particular method used for testing a memory block in accordance with various embodiments of the present invention, it should be observed that the present invention utilizes a combination of method steps and apparatus components related to the method for testing a memory block. Accordingly, the apparatus components and method steps have been represented in the drawings, where appropriate, with conventional symbols, showing only those specific details that are pertinent for an understanding of the present invention, so as not to obscure the disclosure with details that will be readily apparent to those with ordinary skill in the art having the benefit of the description herein.

In this document, the terms ‘comprises,’ ‘comprising,’ ‘includes,’ ‘including,’ or any other variation thereof, are intended to cover a non-exclusive inclusion, such that a process, article, system or apparatus that comprises a list of elements does not include only those elements, but may include other elements not explicitly listed or inherent to such a process, article or apparatus. The term ‘another’, as used in this document, is defined as at least a second or more. The terms ‘includes’ and/or ‘having’, as used herein, are defined as comprising.

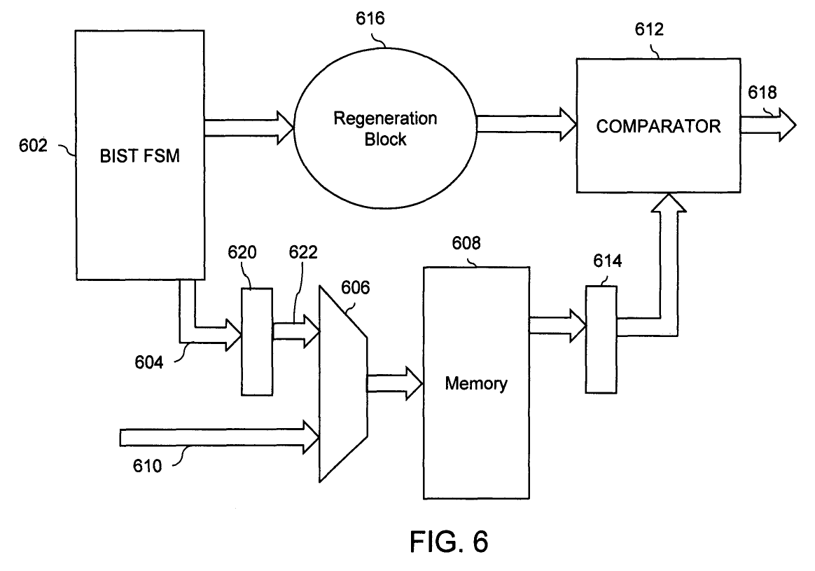

FIG. 6 illustrates a functional block diagram of a BIST with a regeneration block, in accordance with an embodiment of the present invention. In the block diagram, a BIST finite state machine (FSM) 602 is used for generating test patterns by executing a pre-defined algorithm. A finite state machine (not shown in the figure) defines various states for operation, and a test pattern is generated by a signal generator (not shown in the figure) on the basis of the current state of operation. The finite state machine and the signal generator are part of the BIST FSM 602. The BIST FSM 602 generates a test pattern 604 to test a memory address of a memory 608. The test pattern 604 is stored at the memory address of the memory 608 through a pipeline register 620 using a multiplexer 606. The multiplexer 606 is used to define the mode of operation of the memory 608. Under the normal mode of operation, the multiplexer 606 transfers external data and control signals 610 to the memory 608. During the test mode of operation, the multiplexer 606 transfers the test pattern stored in pipeline register 620 to the memory 608. The stored test pattern in the memory address is sent out to a comparator 612 through a pipeline register 614. The person ordinarily skilled in the art will appreciate that the pipeline registers 614 and 620 are used for support of AT-speed testing.

In an embodiment of the invention, the pipeline register 614 and 620 are optional and the invention will work even if the memory 608 is directly connected to comparator 612. In another embodiment of the invention, the pipeline register 614 or 620 can also be replaced with a series of pipeline registers connected in a cascaded chain. A second test pattern for the next memory address is generated by the BIST FSM 602 at a second time instance, at which time the first test pattern 604 is read from the memory address and sent to the comparator 612. A regeneration block 616 is connected between the BIST FSM 602 and the comparator 612. The regeneration block 616 regenerates background data that corresponds to the test pattern 604 and sends the background data to the comparator 612. Background data is the sequence of bits generated by regeneration block 616 corresponding to a previously generated test pattern. When the BIST FSM 602 generates the second test pattern for the next memory address, the regeneration block 616 simultaneously regenerates the background data corresponding to the first test pattern 604. The comparator 612 compares the data read from the memory 608 with the background data and sends out a validity signal 618. The validity signal 618 could either be a pass signal or a fail signal.

In an embodiment of the present invention, the background data is regenerated corresponding to each address at the time of comparison, instead of storing the test pattern in pipeline registers placed between the comparator and the BIST FSM block as mentioned in the prior art. A comparison flag goes high at the time of comparison of the data read from the memory 608 with the background data. By using the regeneration block 616 instead of the pipeline registers, significant area optimization in the BIST block is achieved. Further, the memory will be idle for a fewer number of clock cycles. Hence, stress testing, for which the memory should remain idle for a minimum duration, can be performed.

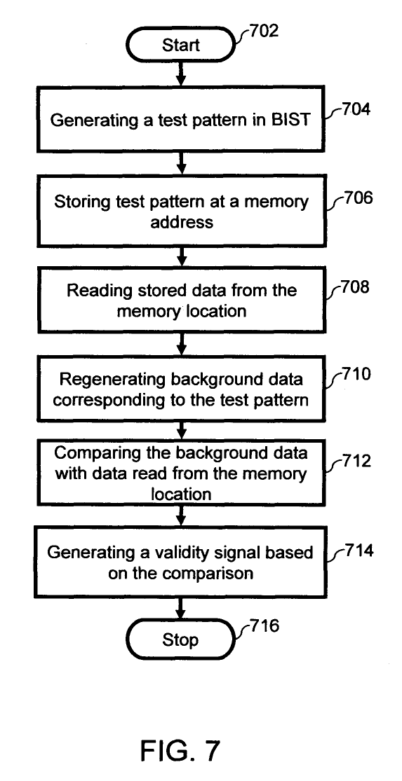

FIG. 7 is a flow diagram illustrating a method of testing a memory address in accordance with an embodiment of the present invention. To describe the flow diagram, reference will be made to FIG. 6, although it should be understood by a person ordinarily skilled in the art that the flow diagram can also be implemented with reference to any other embodiment of the present invention.

The method for testing a memory address of a memory block is initiated at step 702. At step 704, the test pattern 604 is generated in the BIST FSM 602 by executing a pre-defined algorithm. At step 706, the test pattern is stored in an address of the memory 608. Thereafter, at step 708, data is read from the memory address. The read data can either be stored in the pipeline register 614 or can be sent directly to the comparator 612. In an embodiment of the present invention, use of the pipeline register 614 between the memory 608 and the comparator 612 is optional. Also, use of pipeline register 620 between the BIST FSM and memory is optional. According to another embodiment of the invention, a cascaded chain of pipeline registers can be used between the memory 608 and the comparator 612. At step 710, background data is generated in the regeneration block 616. The background data is generated by using at least a part of a predefined algorithm and corresponds to the test pattern 604. At step 712, the background data and the data read from the memory address are compared by the comparator 612. At step 714, the comparator 612 generates the validity signal 618 based on the comparison of the background data and the data read from the memory address. The validity signal 618 could either be a pass or a fail signal. If the background data is a match to the read data, then the validity signal 618 is the pass signal, else the validity signal 618 is the fail signal. Thereafter, the method terminates at step 716.

The disclosed BIST architecture is capable to perform AT-Speed testing and Max-Speed testing of memory. For Max-Speed testing, the memory should be idle for a minimum number of cycles, and for AT-Speed testing the memory should run at the maximum allowable memory speed during the test. This is achieved by generating the test pattern for the current address and comparing background data and read data for a previous address simultaneously.

For the regeneration mechanism of the regeneration block 616, the following parameters are desirable:

a) Address Regeneration: The regeneration block 616 regenerates memory address for which background data is generated. Parameters, equations and algorithm used for address regeneration are described in APPENDIX A.
b) Generating Time of Comparison (comp_flag): It is the duration for which the comparison is delayed after the generation of a test pattern. APPENDIX B provides an algorithm for determining the comparison time.
Background Data Regeneration: Background data is either constant during an operation-set or depends on previous memory address or memory cycle count. Based on the type of read algorithm, background data is dependent on one or more of the following parameters: Current state of FSM; memory address during address regeneration; and regenerated time for comparison (comp_flag). APPENDIX C lists an exemplary algorithm for background data regeneration.

For an exemplary read, write, read MARCHC operation (i.e. r0, w1, r1), the method and system for testing a memory, as described in the present invention, would typically take 917506 clock cycles for a memory block 100K×64. In this example, the memory block has one pipeline register at the input and another at the output. The area required for fabrication on 130 nm technology is 8990 units. Thus, 2447.32 units of fabrication area are saved as compared to the prior art.

The embodiment discussed above provides a method and a system for testing a memory block. The memory block is tested using a BIST architecture having a regeneration block. Use of the regeneration block in BIST architecture instead of using a pipeline register or a cascaded group of pipeline registers reduces the area required for fabricating memory block. In addition to this, AT-Speed testing & Max-Speed testing can be performed and a fewer number of clock cycles is needed for testing, which further enables high stress testing of the memory block.

The method and system for testing a memory, as described in the present invention, may be embodied in the form of a computer system. Typical examples of a computer system include a general-purpose computer, a programmed microprocessor, a micro-controller, a peripheral IC element, and other devices or arrangements of devices that are capable of implementing the steps that constitute the method of the present invention.

The computer system may comprise a computer, an input device, and a display unit. The computer may comprise a microprocessor, which is connected to a communication bus. The computer also includes a memory, which may include Random Access Memory (RAM) and Read Only Memory (ROM). Further, the computer system comprises a storage device, which can be a hard disk drive or a removable storage drive such as a floppy disk drive, an optical disk drive, and the like. The storage device can also be other similar means for loading computer programs or other instructions into the computer system.

The computer system executes a set of instructions that are stored in one or more storage elements to process input data. The storage elements may also store data or other information, as desired, and may be in the form of an information source or a physical memory element present in the processing machine. Exemplary storage elements include a hard disk, a DRAM, an SRAM and an EPROM. Storage elements may also be external to the computer system, and be connected to or inserted into the computer, to be downloaded at or prior to the time of use. Examples of such external computer program products include computer-readable storage mediums such as CD-ROMS, flash chips, floppy disks, and the like.

The set of instructions may include various commands that instruct a processing machine to perform specific tasks, such as the steps that constitute the method of the present invention. The set of instructions may be in the form of a software program. The software may be in various forms, such as system or application software. Further, the software may be in the form of a collection of separate programs, a program module with a larger program, or a portion of a program module. The software may also include modular programming in the form of object-oriented programming. The software program containing the set of instructions can be embedded in a computer program product for use with a computer, with the computer program product comprising a computer-usable medium that has a computer-readable program code embodied therein. Processing of input data by the processing machine may be in response to users' commands, to the result of previous processing, or in response to a request made by another processing machine.

The modules described herein may include processors and program instructions that implement the functions of the modules described herein. Some or all the functions can be implemented by a state machine that has no stored program instructions, or in one or more application-specific integrated circuits (ASICs), in which each function or some combinations of certain of the functions are implemented as custom logic.

In the foregoing specification, the invention and its benefits and advantages have been described with reference to specific embodiments. However, persons with ordinary skill in the art would appreciate that various modifications and changes can be made, without departing from the scope of the present invention, as set forth in the claims. Accordingly, the specification and figures are to be regarded in an illustrative rather than a restrictive sense, and all such modifications are intended to be included within the scope of the present invention. The benefits, advantages, solutions to problems, and any element(s) that may cause any benefit, advantage or solution to occur or become more pronounced are not to be construed as critical, required or essential features or elements of any or all the claims. The invention is defined solely by the appended claims, including any amendments made during the pendency of this application and all equivalents of those claims, as issued.

### APPENDIX A

### Address Regeneration

This appendix includes parameters, equations and algorithms required for address regeneration.

memory_cycle_regen (MCR): MCR is count of memory clock cycles after which regenerated memory address changes.
If Max-Speed is enabled,

MCR=MOD [(Number of Pipeline Stages+1),n] (1a)

MOD is modulo function i.e. Y=MOD [A, B], where A is dividend, B is divisor and Y is remainder.

In the absence of Max-speed,

MCR=MOD [Number of Pipeline Stages,n] (1b)

where, n is number of memory clock cycles required for a compound operation. The compound operation is a sequence of atomic operations performed for a memory address.
memory_cycle_regen_stop (MCRS): MCRS is number of memory clock cycles for which the regenerated memory address remains the same.

MCRS=MOD [(MCR+m−1),m] (2)

where m is number of memory clock cycles required for a compound operation with read operation.
regen_addr_start_threshold (RATh): RATh is the memory address for which the input control signals are generated when address regeneration starts.
If Max-speed is enabled,

RATh=(P+1)*CM/n (3a)

else,

RATh=P*CM/n (3b)

where, P is the number of pipeline registers between the memory block and comparator and CM is the number of column multiplexers in the memory block. P is preferably equal to zero for keeping memory idle for a minimum number of clock cycles without adding any pipeline register.
regen_addr is the address needed to be regenerated for comparison and curr_addr is the current address for which BIST FSM is generating the test pattern. The regen_addr is regenerated using the following algorithm:

regen_addr when MCR>0

if (Curr_addr >= RATh)
{

If (Mem_cycle_cnt >= MCR)
{

regen_addr = curr_addr − RATh;

}
Else
{

| | |
|---|---|
| regen_addr = curr_addr − RATh − 1; | (4a) |

}

}
regen_addr when MCR = 0
{

| | |
|---|---|
| regen_addr = curr_addr − RATh; | (4b) |

}

where Mem_cycle_cnt is the same as memory clock cycle which ranges from 0 to (Cycle count for a compound operation −1) up to the penultimate address.

The number of addresses that need to be compared i.e. ARFC when test pattern for the last memory address is generated, is defined as:

(ARFC)=(P/n)+1 (5)

The number of cycles required to be appended at the end of the current state i.e. CFC, to ensure that the comparison for all the addresses is defined as:

CFC=MCR+(ARFC−1)*n (6)

Therefore at the last address, address regeneration takes place based on the following algorithm:

When MCR > 0

If (Mem cycle cnt <= MCRS)

{

regen_addr = curr_addr −RATh − 1;

}

else {

for (k = 1; k <= ARFC; k = k + 1)
{
if (Mem cycle cnt <= k*T + MCRS)
{

regen_addr = curr_addr − RATh − 1 + k;

}
}

| | |
|---|---|
| } | (4c) |

When MCR = 0
If (Mem cycle cnt <= MCRS)
{

regen_addr = curr_addr − RATh ;

}
else {

for (k = 1; k <= ARFC; k = k + 1)
{

if (Mem cycle cnt <= k*T + MCRS)
{

regen_addr = curr_addr − RATh + k;

}

}

| | |
|---|---|
| } | (4d) |

### APPENDIX B

### Generating Time of Comparison

This appendix includes an algorithm for determining the time of comparison.

If(current_addr != Final_addr) // combinational logic

{

if((Mem cycle cnt >= MCR) && (regen_addr >= RATh))

CTRP = (CRWP + P) % (Cycle count for a compound
operation)

else

CTRP = 0

}
else
{

index = 0;
while(index < ARFC) {

CTRP = (CRWP + P + n * index);
Index = index + 1;

}

| | |
|---|---|
| } | (7) |

if (CF ==1) // combinational logic for comparison
{

if (Mem cycle cnt == CTRP)
{

// comparison logic for generation of pass/fail signal

}

}

where, CF is set to 1 as soon as address regeneration starts .CRWP is comparison time of read, assuming no pipeline register is used and CTRP is comparison time of read after pipeline register between memory block and comparator have been introduced. It should be noted that above two if-else conditions are getting executed concurrently.

When the current_addr points to the final address, there would be total ARFC comparisons since ARFC addresses are left to be regenerated as proved by equation (5).

For a complex compound operation with multiple atomic read operations, CRWP would get asserted for every comparison in absence of AT-speed/Max-speed testing. CTRP follows CRWP being delayed by P clock cycle for AT-speed case and (P+1) clock cycle for Max-speed case

### APPENDIX C

### Background Data Regeneration

This appendix lists an exemplary algorithm for background data regeneration for a read 0, write 1 and read 1 MARCHC operation i.e. r0, w1, r1.

If(Mem cycle cnt < t)
{
Background data = 0;
}
else

{

Background data = 1;

| | |
|---|---|
| } | (8) |

where t is time taken for an atomic read operation.

### APPENDIX D

### Example 1

Appendix D lists an example of a complex MARCHC algorithm (r0, w1, r1) executed in the system of testing memory described in this invention. For example, a read operation takes three cycles (1^{st} clock cycle-generation of input signals, 2^{nd} clock cycle-memory operation, and 3^{rd} clock cycle-comparison operation). Assuming, AT-speed testing, time taken for a compound operation considering with no pipeline register is 7 clock cycles i.e. (3+1+3). For a 1K×32 memory with one pipeline register at the input and another at the output; at time t=0, a BIST block sends a data corresponding to read atomic operation. This value reaches the memory at time t=1 time unit, due to insertion of a pipeline register between the memory and the BIST block. Therefore, the memory operation takes place at time t=2 clock cycle and its value is compared in a BIST comparator circuit at time t=4 clock cycles. So the comparator circuit is enabled at time t=4. The original comparisons are supposed to take place at time t=2 and t=6 (since it is r0,w1,r1 operation there are 2 read operations getting performed). So the new comparison time of first read can be calculated based on the equation (7) as t=4. The background data corresponding to first read is 0 and corresponding to 2^{nd} read is 1.

The second comparison of first address takes place at {MOD [(6+2), 7]=1} time of next memory address. This continues for all the memory addresses, till last memory address. At the last memory address (N) at second time instance (where Mem_cycle_cnt value is 1), comparison for second read of address (N−1) takes place. At time unit 4 (where Mem_cycle_cnt has value 4), the comparison for 1^{st} read operation (of the last memory address N) takes place. The 2^{nd} comparison of the last address (N) takes place at time t={6+2=} 8 time unit.

For a particular state, background data changes depending on the value of time for memory address i.e. the background data is a combinational logic, which generates the background data delayed by clock cycles, equal to total number of pipeline stages. The combinatorial logic generated for the MARCHC algorithm is defined as follows:

### If

((Mem cycle cnt<MOD [(normal time of comparison+total pipeline stages),(time for this compound operation))];

then data1
else data2.

Where data1 is 0x00000000 and data2 is 0xFFFFFFFF.

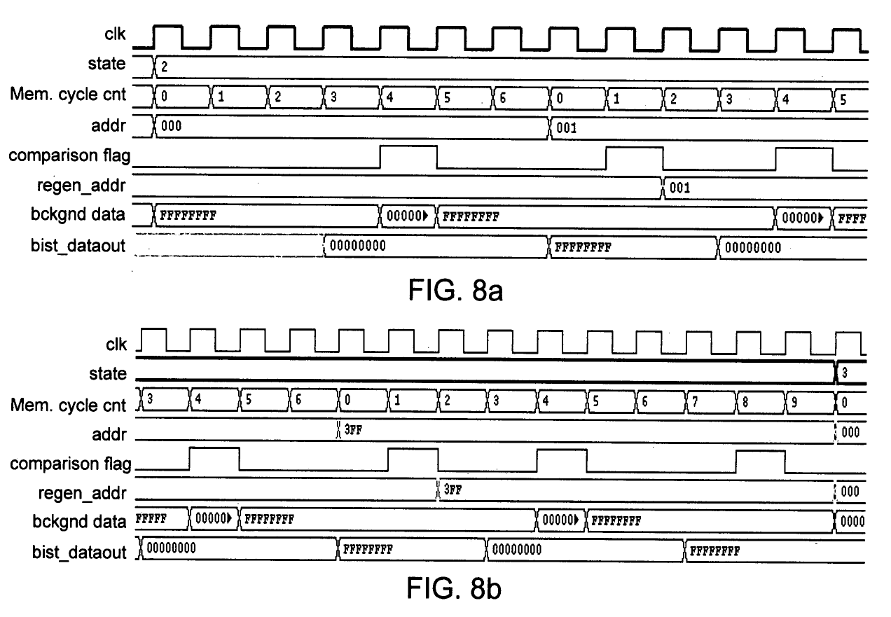

Waveforms for MARCHC operation at first memory address and at last memory address are illustrated in FIG. 8a and FIG. 8b respectively.

### APPENDIX E

### Example 2

Appendix E lists another example of a checkerboard algorithm executed in the system of testing memory described in this invention. The checkerboard read/write cycle is given below:

W, Checkerboard_Data↑

R, Checkerboard_Data ↑

W, Checkerboard_Data↓

R, Checkerboard_Data ↓

where ↑/↓ signifies up/down from address location to minimum/maximum memory address specified by the algorithm.

For a unique address algorithm:
when (addr width>data width)

data={(data_width−1)′b0,addr[0]}+addr[MSB:1];

when (data_width>addr_width)

data={address repeated(data_width/addr_width)times,addr[data_width % addr_width−1:0]}

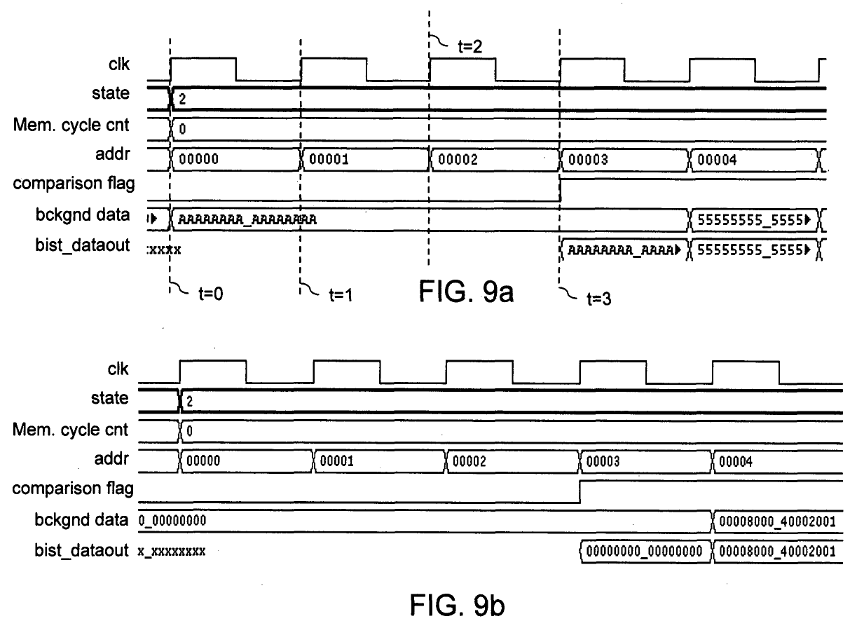

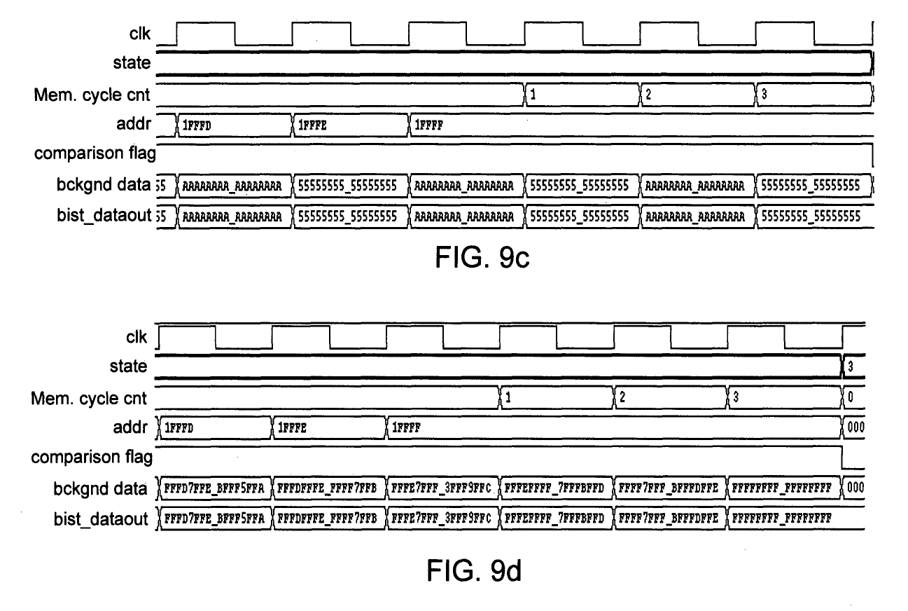

Here “%” represents MOD function defined above. A write operation-set for 100 k×64 memory having one pipeline register each at input and output takes (100 k+3) clock cycles for Max-Speed operation. Typically a read operation takes three cycles (1^{st} clock cycle-generation of input signals, 2^{nd} clock cycle-memory operation, and 3^{rd} clock cycle-comparison operation). Assuming max-speed testing, all three above operations take place simultaneously as shown in FIG. 9a. At time t=0, input signals for memory address are generated, memory output signals are generated at time t=2 and comparison occurs at t=3. Therefore, the regeneration mechanism is activated at t=3. At t=3, input signals for memory address 3 are generated. Also, memory output signals are generated for address 2 and comparison is performed for address 0 at t=3. Therefore, background data regeneration mechanism is delayed by 2 clock cycles. At t=3, background data is generated for memory address 0 and at every clock cycle, background data for next memory address is generated. Hence, memory is idle only for 3 clock cycles in (100k+3) clock cycle in this operation-set. Waveforms for unique address algorithm at first memory address, checkerboard algorithm at last memory address and unique address algorithm at last memory address are illustrated in FIG. 9b, FIG. 9c and FIG. 9d respectively.

What is claimed is:

1. A method for testing one or more memory blocks using a built-in-self-test (BIST) block, the method comprising:
executing a pre-defined algorithm, wherein at least a part of the pre-defined algorithm is provided by the BIST block for regenerating background data;
generating a test pattern by using the pre-defined algorithm to test a memory address, wherein the memory address is a location in a memory block of the one or more memory blocks;
storing the test pattern at the memory address;
reading data from the memory address;
regenerating background data for the test pattern, wherein the background data corresponds to clock cycles taken for storing the test pattern in the memory address, and clock cycles taken for reading the data from the memory address, and wherein the background data is regenerated based on the memory address provided by the BIST block;
comparing the background data with the read data; and
generating a validity signal based on the comparison of the background data with the read data.

2. The method of claim 1 further comprising storing the test pattern in a first set of pipeline registers, wherein an output of the BIST block is an input of the first set of pipeline registers, and wherein an output of the first set of pipeline registers is an input of the memory block.

3. The method of claim 2, wherein the pipeline registers in the first set of pipeline registers are connected as a cascaded chain.

4. The method of claim 2 further comprising reading the test pattern from the first set of pipeline registers.

5. The method of claim 1 further comprising storing the read data in a second set of pipeline registers, wherein an output of the memory block is an input of the second set of pipeline registers, and wherein an output of the second set of pipeline registers is an input of the BIST block.

6. The method of claim 5, wherein pipeline registers in the second set of pipeline registers are connected as a cascaded chain.

7. The method of claim 5 further comprising using the read data from the second set of pipeline registers for comparison.

8. The method of claim 1, wherein the validity signal is a pass signal or a fail signal corresponding to the memory address.

9. A built-in-self-test (BIST) architecture for testing one or more memory blocks, the BIST architecture comprising:
a state machine for generating a test pattern according to a pre-defined algorithm;
a first set of pipeline registers for storing the test pattern to be written on a memory address, wherein the memory address is a location in a memory block of the one or more memory blocks;
a second set of pipeline registers for storing data read from the memory address;
a regeneration block for regenerating a background data for the test pattern, wherein the background data corresponds to clock cycles taken for storing the test pattern in the memory address, and reading the stored data from the memory address, and wherein the background data is regenerated based on the memory address provided by the state machine; and
a comparator for comparing the stored data and the background data, wherein a validity signal is generated based on the comparison of the background data with the stored data.

10. The architecture of claim 9, wherein the state machine further executes the pre-defined algorithm.

11. The architecture of claim 9, wherein an output of the state machine is an input of the first set of pipeline registers, and wherein an output of the first set of pipeline registers is an input of the memory block.

12. The architecture of claim 9, wherein an output of the memory block is an input of the second set of pipeline registers, and wherein an output of the second set of pipeline registers is an input of the state machine.

13. The architecture of claim 9, wherein pipeline registers in the first set of pipeline registers are connected as a cascaded chain.

14. The architecture of claim 9, wherein pipeline registers in the second set of pipeline registers are connected as a cascaded chain.

15. The architecture of claim 9, wherein the validity signal is a pass signal or a fail signal corresponding to the memory address.

16. A computer program product for testing one or more memory blocks using a built-in-self-test (BIST) block, the computer program product comprising a computer readable medium comprising:
program instructions for executing a pre-defined algorithm, wherein at least a part of the pre-defined algorithm is provided by the BIST block for regenerating background data;
program instructions for generating a test pattern by using the pre-defined algorithm to test a memory address, wherein the memory address is a location in a memory block of the one or more memory blocks;
program instructions for storing the test pattern at the memory address;
program instructions for reading data from the memory address;
program instructions for regenerating background data for the test pattern, wherein the background data corresponds to clock cycles taken for storing the test pattern in the memory address, and clock cycles taken for reading the data from the memory address, and wherein the background data is regenerated based on the memory address provided by the BIST block;
program instructions for comparing the background data with the read data; and
program instructions for generating a validity signal based on the comparison of the background data with the read data.
